(19) United States
(12) Patent Application Publication
(10) Pub. No.: US 2010/0006888 A1
(43) Pub. Date: Jan. 14, 2010

(54) METHOD OF MANUFACTURING OPTICAL SEMICONDUCTOR DEVICE, OPTICAL SEMICONDUCTOR DEVICE, AND METHOD OF MANUFACTURING OPTICAL SEMICONDUCTOR APPARATUS

(75) Inventors: Naotake WATANABE, Yokohama-shi (JP); Izuru Komatsu, Yokohama-shi (JP); Kazuo Shimokawa, Yokohama-shi (JP); Hisashi Ito, Fujisawa-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/498,482

(22) Filed: Jul. 7, 2009

(30) Foreign Application Priority Data
Jul. 9, 2008 (JP) 2008-179060

(51) Int. Cl. H01L 33/00; H01L 21/56

(52) U.S. Cl. 257/100; 438/28; 257/E21.502; 257/E33.006; 257/E33.062

(57) ABSTRACT

Provided is a method of manufacturing an optical semiconductor device, the method including: providing a resin layer on a light-emitting substrate to cover a principle surface of the light-emitting substrate, the light-emitting substrate including a pair of electrodes in each section of the principle surface, the resin layer including multiple holes each exposing two of the electrodes located adjacent to each other but in the different sections; providing post electrodes respectively on all the paired electrodes formed in all the sections by filling a conductive material in the holes of the resin layer on the principal surface; and forming multiple optical semiconductor devices by cutting the light-emitting substrate into sections, the light-emitting substrate provided with the post electrodes respectively on all the paired electrodes formed in all the sections.

### CROSS REFERENCE OF THE RELATED APPLICATION

This application is based on and claims the benefit of priority from Japanese Patent Application No. 2008-179060, filed on Jul. 9, 2008; the entire contents of which are incorporated herein by reference.

### BACKGROUND OF THE INVENTION

1. Field of the Invention

The present invention relates to a method of manufacturing an optical semiconductor device, an optical semiconductor device, and a method of manufacturing an optical semiconductor apparatus including the optical semiconductor device.

2. Description of the Related Art

An optical semiconductor device such as a light-emitting diode (LED) is characterized by compact size, high light-intensity relative to input power, long lifetime and no use of any hazardous material such as mercury. Due to such characteristics, the optical semiconductor device has been more and more employed in lighting units such as general lighting units, spot-lighting units and various lighting units in an automobile, as an alternative light source to incandescent and fluorescent lamps.

Generally, such an optical semiconductor device is used after being mounted on a frame or a circuit board for operating the optical semiconductor device. The optical semiconductor device is mounted in such a way that the optical semiconductor device is fixed on a frame or a circuit board with a resin-based adhesive or solder, and that an electrode disposed on the upper surface of the optical semiconductor device is connected to the frame or the circuit board by a wire-bonding method (see JP-A No. 2006-156538 (KOKAI), for example). Meanwhile, the optical semiconductor device may be fixed on a circuit board by a flip-chip method, in some cases.

However, it is difficult to control the amount of resin or solder to be supplied for the mounting of the optical semiconductor device, and the resin or solder is sometimes fed more than necessary. For this reason, a chip of the optical semiconductor device is likely to tilt, thus causing the tilt of the optical axis of outgoing light. Here, optical design is generally made on the assumption that the optical axis of outgoing light is not tilted. Moreover, in the case of the wire-bonding method, a wire interrupts light emitted from the optical semiconductor device, and thereby leads to uneven distribution of the amount of outgoing light. In the case of the flip-chip method, on the other hand, although no wire-bonding process is required, the heat dissipation performance is decreased since only an electrode bump functions as a path through which heat from the optical semiconductor device is dissipated.

### SUMMARY OF THE INVENTION

An object of the present invention is to provide a method of manufacturing an optical semiconductor device, an optical semiconductor device, and a method of manufacturing an optical semiconductor apparatus including the optical semiconductor device. These methods are capable of suppressing the tilt of the optical axis of outgoing light, uneven distribution of the amount of outgoing light, and a decrease in heat dissipation performance.

A first aspect according to an embodiment of the present invention is a method of manufacturing an optical semiconductor device, the method including: providing a resin layer on a light-emitting substrate so as to cover a principle surface of the light-emitting substrate, the light-emitting surface including a pair of electrodes in every section on the principal surface, the resin layer including a plurality of holes each exposing two of the electrodes located adjacent to each other but in the different sections; providing post electrodes respectively on all the paired electrodes formed in all the sections by filling a conductive material in the holes of the resin layer; and forming a plurality of optical semiconductor devices by cutting the light-emitting substrate into the sections, the light-emitting substrate provided with the post electrodes respectively on all the paired electrodes in all the sections.

A second aspect according to the embodiment of the present invention is an optical semiconductor device including: a light-emitting member which includes a principal surface and first and second side surfaces each continuous to the principal surface, and which is configured to emit light; first and second electrodes which are provided on the principal surface; a first post electrode which is provided on the first electrode, and which extends to the first side surface; a second post electrode which is provided on the second electrode, and which extends to the second side surface; and a resin member which is provided on the principal surface while exposing surfaces including: a surface, opposed to the light-emitting member, of the first post electrode; a surface of the first post electrode on the first side surface side; a surface, opposed to the light-emitting member, of the second post electrode; and a surface of the second post electrode on the second side surface side.

A third aspect according to the embodiment of the present invention is a method of manufacturing an optical semiconductor apparatus by mounting, on a device substrate, an optical semiconductor device including: a light-emitting member which includes a principal surface and first and second side surfaces each continuous to the principal surface, and which is configured to emit light; first and second electrodes which are provided on the principal surface; a first post electrode which is provided on the first electrode, and which extends to the first side surface; a second post electrode which is provided on the second electrode, and which extends to the second side surface; and a resin member which is provided on the principal surface while exposing surfaces including: a surface, opposed to the light-emitting member, of the first post electrode; a surface of the first post electrode on the first side surface side; a surface, opposed to the light-emitting member, of the second post electrode; and a surface of the second post electrode on the second side surface side. In the method, with a bond, the device substrate is bonded to the surface of the first post electrode on the first side surface side and the surface of the second post electrode on the second side surface side.

### BRIEF DESCRIPTION OF THE DRAWINGS

FIG. 1 is an external perspective view showing a schematic configuration of an optical semiconductor device according to an embodiment of the present invention.

FIG. 2 is a cross-sectional view taken along a line A1-A1 of FIG. 1.

FIG. 3 is a perspective view showing a light-emitting substrate used for manufacturing the optical semiconductor device shown in FIGS. 1 and 2

FIG. 4 is a perspective view showing a principal surface of the light-emitting substrate shown in FIG. 3 in an enlarged manner.

FIG. 5 is a cross-sectional view showing a first step of a manufacturing process of the optical semiconductor device shown in FIGS. 1 and 2.

FIG. 6 is a cross-sectional view showing a second step thereof.

FIG. 7 is a cross-sectional view showing a third step thereof.

FIG. 8 is a cross-sectional view showing a first step of a manufacturing process of an optical semiconductor apparatus.

FIG. 9 is a cross-sectional view showing a second step thereof.

### DESCRIPTION OF THE PREFERRED EMBODIMENTS

An embodiment of the present invention will be described with reference to the drawings.

### (Optical Semiconductor Device)

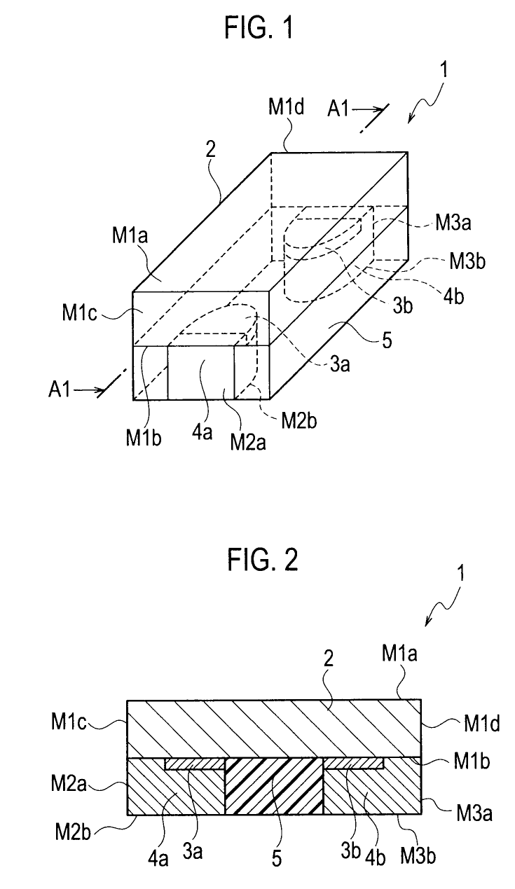

As shown in FIGS. 1 and 2, an optical semiconductor device 1 according to the embodiment of the present invention includes: a light-emitting member 2 which emits light, and which has a first principal surface M1a and a second principal surface M1b opposed to the first principal surface M1a; first and second electrodes 3a and 3b which are provided on the second principal surface M1b; a first post electrode 4a which is provided on the first electrode 3a; a second post electrode 4b which is provided on the second electrode 3b; and a resin member 5 which is provided on the second principal surface M1b while exposing parts of the first and second post electrodes 4a and 4b.

The light-emitting member 2 includes a device body which serves as a substrate; a light-emitting layer (optical semiconductor layer) which is provided on the device body and emits light; an electrode layer which is provided on the light-emitting layer; and the like. The light-emitting member 2 has a rectangular parallelepiped shape, and has a thickness of around 100 μm, for example.

The first and second electrodes 3a and 3b are a pair of electrodes for applying a voltage to the light-emitting layer of the light-emitting member 2. The first and second electrodes 3a and 3b are formed on the second principal surface M1b of the light-emitting member 2 so as to be located apart from each other on the same straight line.

The first and second post electrodes 4a and 4b serve as a pair of current lines which passes electric current through the first and second electrodes 3a and 3b. The first post electrode 4a is stacked on the first electrode 3a and extends to a first side surface M1c of the light-emitting member 2. Meanwhile, the second post electrode 4b is stacked on the second electrode 3b and extends to a second side surface M1d of the light-emitting member 2. Hence, a surface M2a of the first post electrode 4a on the first side surface M1c side and a surface M3a of the second post electrode 4b on the second side surface M1d side are exposed. The first and second post electrodes 4a and 4b each have a thickness approximately the same as that of the light-emitting member 2 (around 100 μm, for example); however, the thickness is not limited to this, and may be several μm or several tens of μm.

The resin member 5 is an insulating prepreg member which has a rectangular parallelepiped shape, for example. The resin member 5 is provided on the second principal surface M1b of the light-emitting member 2 while exposing parts of the first and second post electrodes 4a and 4b, that is, the following surfaces: the surface M2a, on the side of the first side surface M1c of the light-emitting member 2, of the first post electrode 4a; a surface M2b, opposed to the light-emitting member 2, of the first post electrode 4a; the surface M3a, on the side of the second side surface M1d of the light-emitting member 2, of the second post electrode 4b; and a surface M3b, opposed to the light-emitting member 2, of the second post electrode 4b. Here, a material having a high thermal conductivity is preferably used as a material for the resin member 5, and a resin material including filler, such as Al₂O₃, can be used. The resin member 5 has a thickness approximately the same as that of the light-emitting member 2 (around 100 μm, for example); however, the thickness is not limited to this, and may be several pm or several tens of μm.

Such an optical semiconductor device 1 is bonded to another member, such as a frame or a circuit board, by being brought into close contact therewith using a bond such as solder or resin (described in detail later). The optical semiconductor device 1 emits light through the light-emitting member 2 in such a manner that the first and second post electrodes 4a and 4b are supplied with a voltage, and that the first and second electrodes 3a and 3b are applied with the voltage. Here, although completely covered with the first and second post electrodes 4a and 4b and the resin member 5, the first and second electrodes 3a and 3b are supplied with electric current through the first and second post electrodes 4a and 4b. Note that, heat generated in the light-emitting member 2 is diffused (dissipated) through the first and second electrodes 3a and 3b as well as the first and second post electrodes 4a and 4b, and is further diffused through the resin member 5 which is in close contact with another member, such as a frame or a circuit board.

### (Method of Manufacturing Optical Semiconductor Device)

Subsequently, a description will be given of a method of manufacturing the optical semiconductor device 1.

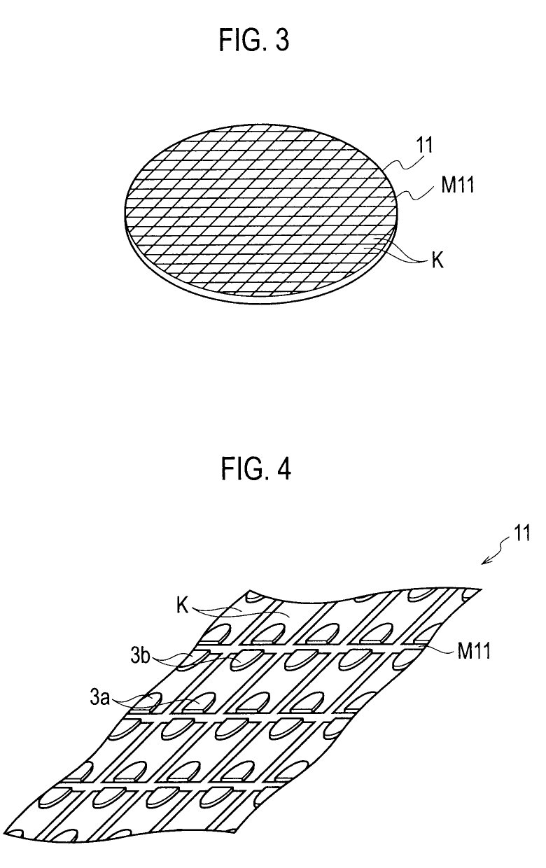

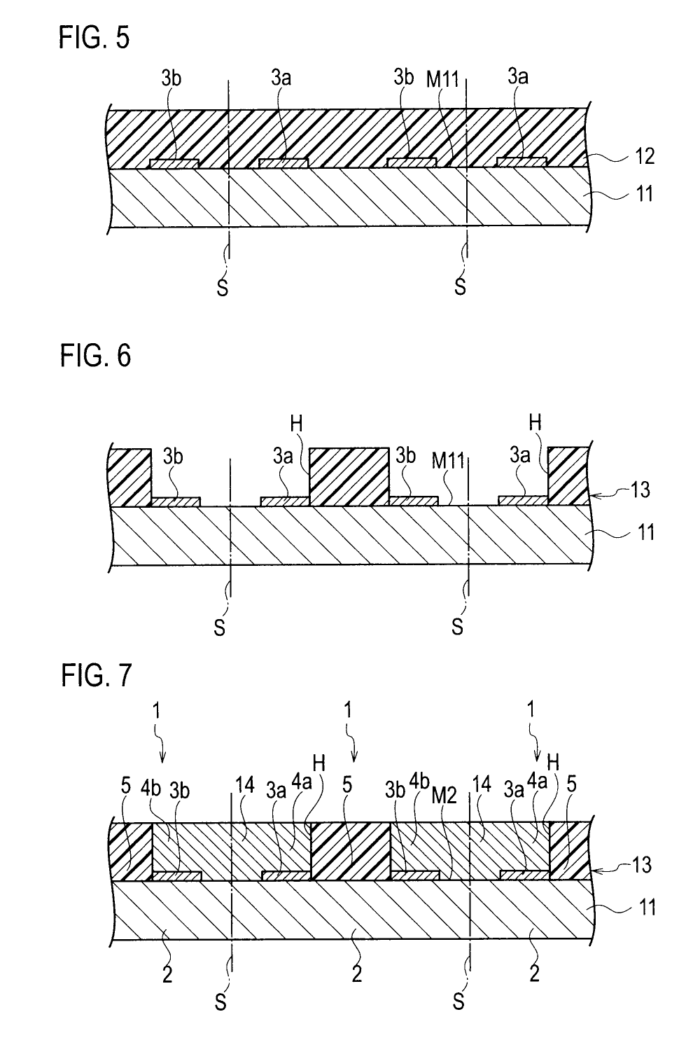

In a process of manufacturing the optical semiconductor device 1 according to the embodiment of the present invention, multiple optical semiconductor devices 1 are manufactured by using a light-emitting substrate 11 such as a sapphire wafer as shown in FIGS. 3 and 4. This manufacturing process includes: a stacking step of stacking a full-coverage resin layer (full-coverage prepreg layer) 12 on a principal surface M11 of the light-emitting substrate 11, as shown in FIG. 5; a removing step of partially removing the full-coverage resin layer 12 on the light-emitting substrate 11 and thus forming a resin layer (prepreg layer) 13 including multiple holes H, as shown in FIG. 6; a filling step of filling each hole H of the resin layer 13 with a conductive material 14, as shown in FIG. 7; and finally a cutting step of cutting the light-emitting substrate 11 thus filled with the conductive material 14 into small pieces.

On the principal surface M11 of the light-emitting substrate 11, the first and second electrodes 3a and 3b (a pair of electrodes) are formed in every section K which corresponds to the optical semiconductor device 1 of a desired dimension (design value), as shown in FIGS. 3 and 4. The light-emitting substrate 11 is an assembly of the light-emitting members 2, and the principal surface M11 of the light-emitting substrate 11 is an assembly of the second principal surfaces M1b of the respective light-emitting members 2. The light-emitting substrate 11 has a thickness of around 100 μm, for example.

In the stacking step, as shown in FIG. 5, a resin sheet (prepreg sheet) is attached on the principal surface M11 of the light-emitting substrate 11, so that the full-coverage resin layer 12 is stacked on the principal surface M11 of the light-emitting substrate 11. Then, the resultant layer is subjected to a pre-curing process. Thus, the principal surface M11 of the light-emitting substrate 11, the first electrodes 3a and the second electrodes 3b (the pair of electrodes 3a and 3b which is formed in every section K) are completely covered with the full-coverage resin layer 12. The full-coverage resin layer 12 has a thickness of around 100 μm, for example. Here, a thermosetting resin, such as an epoxy resin, can be used for a material of the resin sheet. A resin material including filler, such as Al₂O₃, is preferably used to improve thermal conductivity. For such a resin supply process, a process of coating an insulating resin (spin coat process, for example) can be employed besides a process of attaching a resin sheet.

In the removing step, as shown in FIG. 6, the full-coverage resin layer 12 on the principal surface M11 of the light-emitting substrate 11 is partially removed by carbon dioxide laser or the like so that the holes H may be formed in the full-coverage resin layer 12. The holes H each expose the electrode 3a and the electrode 3b which are located adjacent to each other but in the different sections K. In this way, the resin layer 13 including the holes H is formed. FIG. 6 shows that one hole H is formed for each adjacent two of the first electrode 3a and the second electrode 3b. Here, surfaces, opposed to the light-emitting substrate 11, of the first electrode 3a and the second electrode 3b are exposed by the hole H. Further, facing surfaces of each adjacent two of the first electrode 3a and the second electrode 3b are also exposed by the hole H.

In this embodiment, the resin layer 13 including the holes H is formed on the principal surface M11 of the light-emitting substrate 11 by stacking the full-coverage resin layer 12 on the principal surface M11 of the light-emitting substrate 11 and then by partially removing the full-coverage resin layer 12; however, the present invention is not limited to this. For example, a resin sheet including the holes H may be formed in advance by using a mold or the like to then attach the resin sheet on the principal surface M11 of the light-emitting substrate 11. In this case, although the resin sheet needs to be positioned relative to the light-emitting substrate 11, the number of steps can be reduced as compared to the case of performing the partial removal as described above.

In the filling step, as shown in FIG. 7, the conductive material 14, such as a Cu paste, is fed by printing and filled in the holes H in the resin layer 13 on the light-emitting substrate 11. Thereafter, a curing process is performed. The conductive material 14 serves as the first and second post electrodes 4a and 4b after the subsequent cutting process is performed. In this embodiment, the conductive material 14 is fed in the holes H by printing; however, the present invention is not limited to this. For example, the conductive material 14 may be fed through a plating process.

In the cutting step, as shown in FIG. 7, the light-emitting substrate 11 with the conductive material 14 filled in the holes H is cut along a cut position (scribing position) S provided for every section K. Specifically, the light-emitting substrate 11 with the conductive material 14 filled in the holes H is diced along the cut position S into small pieces with a dicing blade. By doing so, multiple optical semiconductor devices 1 as shown in FIGS. 1 and 2 are manufactured at one time. In this embodiment, the section K is rectangular in shape; however, the shape is not limited to this.

### (Method of Manufacturing Optical Semiconductor Apparatus)

Next, a description will be given of a method of manufacturing an optical semiconductor apparatus 21 including the optical semiconductor device 1 described above.

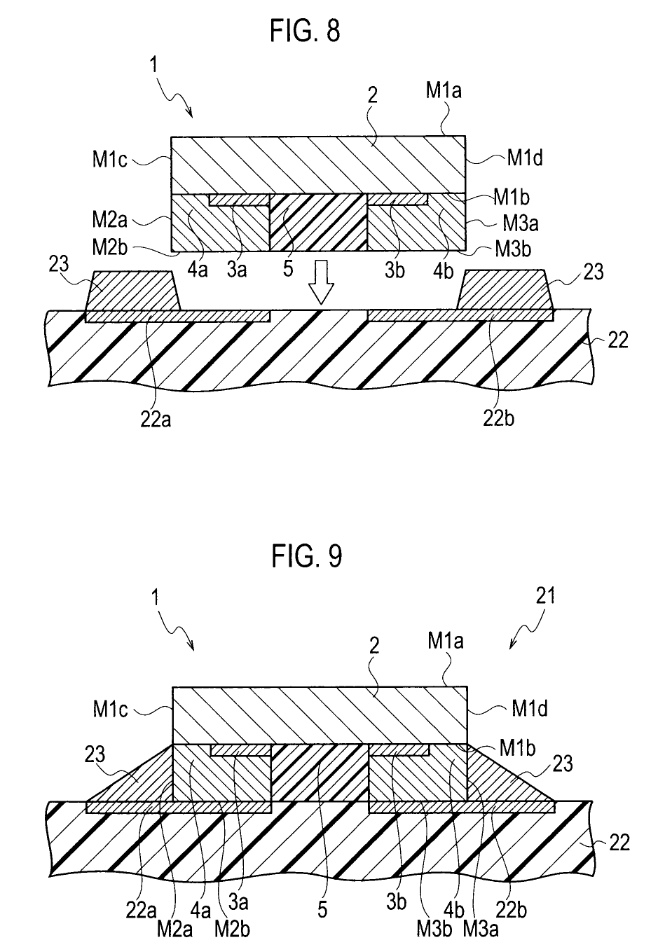

In the method of manufacturing the optical semiconductor apparatus 21 according to an embodiment of the present invention, the optical semiconductor device 1 is bonded to a device substrate 22, such as a frame or a circuit board, to manufacture the optical semiconductor apparatus 21, as shown in FIGS. 8 and 9. This manufacturing process includes: a feeding step of feeding an uncured bond 23 to each of electrode pads 22a and 22b of the device substrate 22, as shown in FIG. 8; a placing step of placing the optical semiconductor device 1 on the device substrate 22 thus fed with the bond 23; and a bonding step of melting and curing the bond 23 after placing the optical semiconductor device 1 so that the optical semiconductor device 1 may be bonded to the device substrate 22, as shown in FIG. 9.

In the feeding step, as shown in FIG. 8, the bond 23 is fed to a part of each of the electrode pads 22a and 22b. At this time, the bond 23 is fed to regions partly including a placing region, on which the optical semiconductor device 1 is to be placed, of the electrode pads 22a and 22b. In this way, the optical semiconductor device 1 comes into contact with the uncured bond 23 when placed on the device substrate 22. Thereby, the optical semiconductor device 1 having been placed on the device substrate 22 is prevented from moving owing to the adhesiveness of the uncured bond 23. As the bond 23, solder (a solder paste), a resin-based adhesive, or the like is used.

In this embodiment, the bond 23 is fed to the regions partly including the above placing region for the optical semiconductor device 1 of the electrode pads 22a and 22b; however, the present invention is not limited to this. For example, the bond 23 may be fed to only a region not including the placing region. In this case, the bond 23 is melted in the bonding step, and moves along the electrode pads 22a and 22b to thereby come into contact with the optical semiconductor device 1 placed on the device substrate 22.

In the placing step, as shown in FIG. 8, the optical semiconductor device 1 is positioned relative to the device substrate 22 fed with the bond 23 and is then placed on the device substrate 22. Here, the optical semiconductor device 1 is positioned in a region partly including the electrode pads 22a and 22b, the region being surrounded by the bond 23.

In the bonding step, as shown in FIG. 9, the device substrate 22 on which the optical semiconductor device 1 is placed is put in a reflow oven (reflow device), and the bond 23 is heated and melted therein. At this time, the optical semiconductor device 1 is pressed against the device substrate 22 to be brought into close contact therewith. Thereafter, the bond 23 is cooled, so that the optical semiconductor device 1 is bonded to the device substrate 22. In this manner, the optical semiconductor apparatus 21 is completed. To be more specific, with the bond 23, the electrode pad 22a of the device substrate 22 is bonded to the surface M2a of the first post electrode 4a on the first side surface M1c side, and the electrode pad 22b of the device substrate 22 is bonded to the surface M3a of the second post electrode 4b on the second side surface M1d side. Accordingly, the optical semiconductor device 1 is fixed to the device substrate 22.

As described above, the optical semiconductor device 1 is fixed to the device substrate 22, such as a frame or a circuit board, by using the bond 23 such as solder or resin. Thus, the optical semiconductor device 1 is bonded to the device substrate 22 without using the wire-bonding process. Further, the optical semiconductor device 1 is bonded to the device substrate 22 while being in close contact therewith. This eliminates the need to use the wire-bonding method, and thereby prevents the tilt of a chip resulting from this wire-bonding process. This makes it possible to suppress the tilt of the optical axis of outgoing light. Moreover, this eliminates the need to use a wire, thus suppressing uneven distribution of the amount of outgoing light resulting from the wire. Additionally, the entire bottom surface of the optical semiconductor device 1 is brought into close contact with the device substrate 22, so that a heat dissipation area is increased as compared to the case of using the flip-chip method where only an electrode bump functions as a path through which heat from the chip is dissipated. As a result, a decrease in the heat dissipation performance can be suppressed.

As has been described, according to the embodiment of the present invention, the resin layer 13 including the holes H is formed on the light-emitting substrate 11 so as to cover the principal surface M11, the light-emitting substrate 11 including the pair of electrodes 3a and 3b in every section K, the holes H each exposing the electrode 3a and the electrode 3b which are located adjacent to each other but in the different sections K; the conductive material 14 is filled in the holes H of the resin layer 13 so that the post electrodes 4a and 4b may be provided respectively on all the paired electrodes 3a and 3b formed in all the sections K; the light-emitting substrate 11 with the post electrodes 4a and 4b provided on all the paired electrodes 3a and 3b formed in all the sections K is cut into the sections K to form multiple optical semiconductor devices 1. In this manner, multiple optical semiconductor devices 1 are manufactured at one time.

When the optical semiconductor device 1 thus manufactured is mounted on the device substrate 22 such as a frame or a circuit board, with the bond 23 such as solder or resin, the device substrate 22 is bonded to the surface M2a of the first post electrode 4a on the first side surface M1c side and the surface M3a of the second post electrode 4b on the second side surface M1d side. Thereby, the optical semiconductor device 1 is fixed to the device substrate 22 while being in close contact therewith.

Thus, the optical semiconductor device 1 is bonded to the device substrate 22, such as a frame or a circuit board, without using the wire-bonding process. Further, the optical semiconductor device 1 is bonded to the device substrate 22 while being in close contact therewith. This eliminates the need to use the wire-bonding method. Additionally, the entire bottom surface of the optical semiconductor device 1 is brought into close contact with the device substrate 22, so that a heat dissipation area is increased as compared to the case of using the flip-chip method where only an electrode bump functions as a path through which heat from a chip is dissipated. As a result, the tilt of the optical axis of outgoing light, uneven distribution of the amount of outgoing light, and a decrease in the heat dissipation performance can be suppressed.

Meanwhile, the resin layer 13 is formed on the principal surface M11 of the light-emitting substrate 11 in such a manner that: the full-coverage resin layer 12 entirely covering the principal surface M11 and the pairs of electrodes 3a and 3b formed in all the sections K is stacked on the principal surface M11 of the light-emitting substrate 11; and the full-coverage resin layer 12 on the principal surface M11 is partially removed to form the multiple holes H in the full-coverage resin layer 12 on the principal surface M11. In this way, the resin layer 13 including the holes H can be formed with a simple process without using a mold and the like.

It should be noted that the present invention is not limited to the embodiments described above, and can be modified in various way without deviating from the gist thereof. For example, various materials are employed in the aforementioned embodiments; however, these materials are merely an example, and the present invention is not limited to these. In addition, various numeric values are employed in the aforementioned embodiments; however, these numeric values are merely an example, and the present invention is not limited to these.

What is claimed is:

1. A method of manufacturing an optical semiconductor device, comprising:
providing a resin layer on a light-emitting substrate so as to cover a principle surface of the light-emitting substrate, the light-emitting surface including a pair of electrodes in every section on the principal surface, the resin layer including a plurality of holes each exposing two of the electrodes located adjacent to each other but in the different sections;
providing post electrodes respectively on all the paired electrodes formed in all the sections by filling a conductive material in the holes of the resin layer; and
forming a plurality of optical semiconductor devices by cutting the light-emitting substrate into the sections, the light-emitting substrate provided with the post electrodes respectively on all the paired electrodes in all the sections.

2. The method of manufacturing an optical semiconductor device according to claim 1,
wherein the resin layer is provided on the light-emitting substrate in such a manner that
a full-coverage resin layer entirely covering the principal surface of the light-emitting substrate and the pairs of electrodes formed in all the sections is stacked on the principal surface, and
the full-coverage resin layer on the principal surface is partially removed to form the holes in the full-coverage resin layer on the principal surface.

3. An optical semiconductor device comprising:
a light-emitting member which includes a principal surface and first and second side surfaces each continuous to the principal surface, and which is configured to emit light;
first and second electrodes which are provided on the principal surface;
a first post electrode which is provided on the first electrode, and which extends to the first side surface;
a second post electrode which is provided on the second electrode, and which extends to the second side surface; and
a resin member which is provided on the principal surface while exposing surfaces including:
a surface, opposed to the light-emitting member, of the first post electrode;
a surface of the first post electrode on the first side surface side;
a surface, opposed to the light-emitting member, of the second post electrode; and
a surface of the second post electrode on the second side surface side.

4. A method of manufacturing an optical semiconductor apparatus by mounting, on a device substrate, an optical semiconductor device including:
a light-emitting member which includes a principal surface and first and second side surfaces each continuous to the principal surface, and which is configured to emit light;
first and second electrodes which are provided on the principal surface;
a first post electrode which is provided on the first electrode, and which extends to the first side surface;
a second post electrode which is provided on the second electrode, and which extends to the second side surface; and
a resin member which is provided on the principal surface while exposing surfaces including:
a surface, opposed to the light-emitting member, of the first post electrode;
a surface of the first post electrode on the first side surface side;
a surface, opposed to the light-emitting member, of the second post electrode; and
a surface of the second post electrode on the second side surface side,
wherein, with an bond, the device substrate is bonded to the surface of the first post electrode on the first side surface side and the surface of the second post electrode on the second side surface side.
